(19) United States
(12) Patent Application Publication
(10) Pub. No.: US 2011/0284077 A1
(43) Pub. Date: Nov. 24, 2011

(54) PROTECTION APPARATUS FOR A SOLAR RECEIVER

(76) Inventors: Mark Andrew Stedwell, Victoria (AU); Simon James Hobbs, Victoria (AU); Arjun Vinoo Caprihan, Victoria (AU); Simon Mann, Victoria (AU); John Beavis Lasich, Victoria (AU)

(21) Appl. No.: 13/129,096

(22) PCT Filed: Nov. 12, 2009
(86) PCT No.: PCT/AU2009/001472

§ 371 Date: Aug. 12, 2011

Related U.S. Application Data
(60) Provisional application No. 61/113,990, filed on Nov. 12, 2008.

(51) Int. Cl. H01L 31/0232; G02B 7/183; G02B 7/00; G02B 5/26; H01L 31/024; G02B 5/20

(52) U.S. Cl. 136/259; 359/892; 359/872

(57) ABSTRACT

Protection apparatus for protecting a photovoltaic solar energy receiver from overheating due to concentrated solar radiation reflected from mirrors towards the receiver, the protection apparatus comprising: a shield arranged to move between a stowed position out of a path of solar radiation onto the receiver and a shielding position in the path of solar radiation, unless restrained in the stowed position; and a restraint mechanism for restraining the shield in the stowed position.

### FIELD

The present invention relates to a protection apparatus for a solar receiver, as well as to a solar receiver and a solar generator incorporating the protection apparatus.

### BACKGROUND

One type of solar power generator is a photovoltaic power generator having solar receiver comprised of a dense array of photovoltaic cells onto which is focussed solar radiation from mirrors at a concentration factor of 500 or more. The photovoltaic cells can be destroyed, irreparably damaged, or reduced in lifetime in the event of cooling system failure. Some such power generators have been designed with heat extraction systems such as heat sinks in close thermal contact with the photovoltaic cells, and cooling circuits through which coolant is pumped to maintain the heat sinks and photovoltaic cells at an appropriate operating temperature.

Previous approaches to additional protection of solar receivers such as photovoltaic cell receivers in dense array concentrator photovoltaic systems (CPV) have been either to maintain emergency power storage and backup to enable controlled direction of the dish or heliostat collectors to divert the solar radiation away from the receiver when there is a failure, or to maintain a supply of coolant in a tower which feeds by gravity through the receiver in the event of loss of coolant pumping.

The current inventors have found that in the long term operation of CPV installations protection via coolant only dues not protect against all failure modes that may damage the sensitive photovoltaic cells and/or has cost and other disadvantages.

There is a need for an alternative approach to protect solar receivers from overheating.

### SUMMARY OF THE INVENTION

In a one aspect, the invention provides protection apparatus for protecting a photovoltaic solar energy receiver from overheating due to concentrated solar radiation reflected from mirrors towards the receiver, the protection apparatus comprising:
a shield arranged to move between a stowed position out of a path of solar radiation onto the receiver and a shielding position in the path of solar radiation, unless restrained in the stowed position; and
a restraint mechanism for restraining the shield in the stowed position.

In an embodiment, the restraint mechanism restrains the shield when active such that when the restraint mechanism is not active, the shield moves to the shielding position.

In an embodiment, the restraint mechanism comprises at least one actuator, such that the restraint mechanism is active when adequate actuator power supply is supplied.

In an embodiment, each actuator is a pneumatic cylinder such that the restraint mechanism is active when adequate air is supplied to a cylinder chamber of the pneumatic cylinder.

In an embodiment, the protection apparatus comprises at least one valve moveable to a venting position to vent compressed from the cylinder chamber to deactivate the restraint mechanism.

In an embodiment, the protection apparatus comprises at least two valves connected such that the movement of either valve to the venting position deactivates the restraint mechanism.

In an embodiment, the actuator is an electric motor coupled to the shield such that the restraint mechanism is active when adequate electric power is supplied to the electric motor.

In an embodiment, the shield is mounted to a shaft around which the shield can rotate and the electric motor is coupled to the shaft.

In an embodiment, the restraint mechanism is moveable from a restraining position to a non-restraining position.

In an embodiment, the protection apparatus comprises a shield movement mechanism adapted to move the shield between the stowed position and the shielding position when the shield is not restrained.

In an embodiment, the restraint mechanism restrains the shield by restraining the shield movement mechanism.

In an embodiment, the protection apparatus comprises a control mechanism adapted to cause the shield to be moved to the shielding position when at least one protection condition is met.

In an embodiment, the control mechanism deactivates the restraint mechanism when the at least one protection condition is met.

In an embodiment, the control mechanism comprises an electrical circuit and a switch is provided for each protection condition such than when a protection condition is met the associated switch moves to the open position.

In an embodiment, the protection condition comprises at least one of: inadequate coolant flow; inadequate actuator power supply; and over temperature.

In an embodiment, the control mechanism is arranged to control the restraint mechanism such that it moves from the restraining position to the non-restraining position when at least one protection condition is met.

In an embodiment, the shield is disposed in the shielding position to be displaced relative to the most concentrated solar radiation at a focal point of the concentrated solar radiation to thereby encounter lower temperatures.

In an embodiment, a front face of the shield has high reflectivity.

In an embodiment, a front face of the shield has high emissivity.

In an embodiment, a back face of the shield has low emissivity.

In another aspect, the invention provides a solar power generator comprising:
a photovoltaic solar energy receiver for receiving and converting concentrated solar radiation into electrical power;
at least one concentrator for concentrating the solar radiation on the solar energy receiver; and
a protection apparatus as described above.

In another aspect, the invention provides a method of protecting a photovoltaic solar receiver from overheating due to concentrated solar radiation reflected from mirrors towards the receiver, the protection apparatus comprising:
restraining a shield in a stowed position away from a path of solar radiation onto the receiver; and
causing the shield to move to a shielding position blocking the path of solar radiation when the shield is not restrained in the stowed position.

In another aspect, the invention provides a method of producing electrical power comprising operating the solar power generator described above.

### BRIEF DESCRIPTION OF THE DRAWINGS:

Embodiments of the invention are described further by way of example with reference to the accompanying drawings, in which:

FIG. 1 is a perspective view of an exemplary system for generating electrical power from solar radiation;

FIG. 2 is a front view of a receiver of the system shown in FIG. 1 which illustrates the exposed surface area of the photovoltaic cells of the receiver;

FIG. 3 is a front view of another receiver of the system shown in FIG. 1 which illustrates the exposed surface area of the photovoltaic cells of the receiver;

FIG. 4 is a perspective view of a receiver with components removed to illustrate more clearly the coolant circuit that forms part of the receiver;

FIG. 5 is a perspective view of another receiver with components removed to illustrate more clearly the coolant circuit that forms part of the receiver;

FIG. 6 is a perspective view of a receiver with a first embodiment of a protection apparatus with shield in a shielding position;

FIG. 7 is a perspective view of a receiver with a second embodiment of a protection apparatus with the shield in a shielding position;

FIG. 8 is a side view of a protection apparatus of the first embodiment, with the shield in a stowed position;

FIG. 9 is a side view of a protection apparatus of the second embodiment the shield in a stowed position;

FIG. 10 is a view of the external actuator mechanism of the first embodiment;

FIG. 11 is a view of an internal actuator mechanism of the second embodiment; and

FIG. 12 is a schematic view of a switching arrangement for the actuator of the first embodiment.

FIG. 13 is a circuit diagram of an embodiment of a control mechanism.

### DETAILED DESCRIPTION

The embodiments provide a protection apparatus having a shield adapted to move to a shielding position to protect a receiver unless restrained at a stowed position by a restraining mechanism. In an embodiment, the shield and the restraining mechanism are arranged such that the shield will move from the stowed position unless the restraining mechanism is active, such that if the restraining mechanism is deactivated intentionally or due to a failure of operation, the shield will move to protect the receiver.

The embodiments are of particular use in solar power generation systems which employ a concentrator and a photovoltaic receiver in electricity generation.

Exemplary Power Generation System

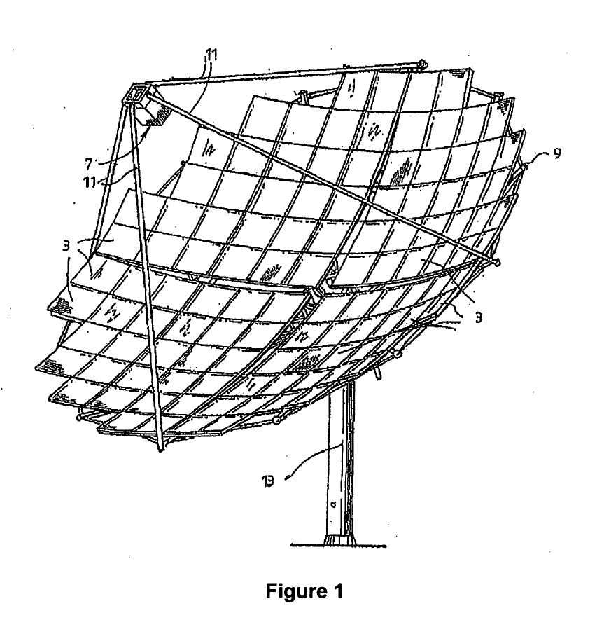

An exemplary solar radiation-based electric power generating system shown in FIG. 1 includes a concentrator 3 in the form of an array of mirrors that reflects solar radiation that is incident on the mirrors towards a plurality of photovoltaic cells 5.

The cells 5 form part of a solar energy receiver 7 that includes an integrated coolant circuit. The surface area of the concentrator 3 that is exposed to solar radiation is substantially greater than the surface area of the photovoltaic cells 5 that is exposed to reflected solar radiation. The photovoltaic cells 5 convert reflected solar radiation into DC electrical energy. The receiver 7 includes an electrical circuit (not shown) for the electrical energy output of the photovoltaic cells.

The concentrator 3 is mounted to a framework 9. A series of arms 11 extend from the framework 9 to the receiver 7 and locate the receiver as shown in FIG. 1. The system further includes: (a) a support assembly 13 that supports the concentrator and the receiver in relation to a ground surface and for movement to track the Sun; and (b) a tracking system (not shown) that moves the concentrator 3 and the receiver 7 as required to track the Sun.

As described in further detail in WO 02/080286 which is owned by the present applicant, Solar Systems Pty Ltd, the amount of heat generated by the concentrated light can lead to problems with the operating temperature and performance of the cells 5. To this end, the receiver 7 includes a coolant circuit such as described in WO 02/080286 which can be applied to a wide range of solar cells, including multi-junction solar cells.

The coolant circuit cools the photovoltaic cells 5 of the receiver 7 with a coolant, preferably water, in order to maintain a safe operating temperature and to maximise the performance (including operating life) of the photovoltaic cells 5.

FIG. 3 illustrated components of the receiver that are relevant to an exemplary coolant circuit. Other cooling arrangements may also be employed. A number of other components of the receiver 7, such as components that make up the electrical circuit of the receiver 7, are not included in the FIGS. 1 to 3 for clarity.

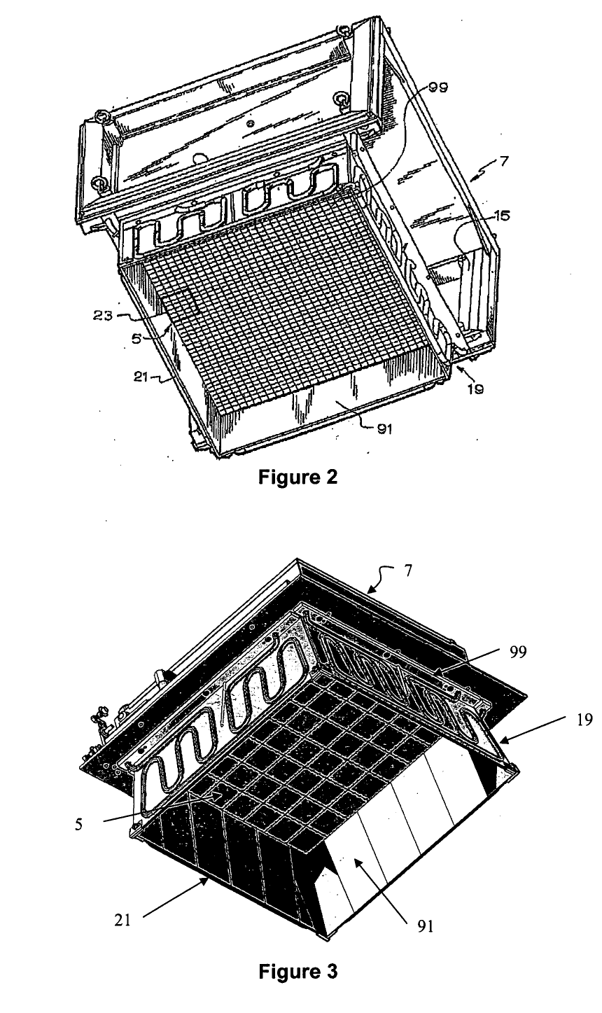

With reference to FIG. 3 the receiver 7 has a generally box-like structure. The receiver 7 also includes a solar flux modifier, generally identified by the numeral 19, which extends from a lower wall 99 (as viewed in FIGS. 2 & 3) of the box-like structure. The solar flux modifier 19 includes four panels 21 that extend from the lower wall 99 and converge toward each other. The solar flux modifier 19 also includes mirrors 91 mounted to the inwardly facing sides of the panels 21.

The receiver 7 also includes a dense array of 1536 closely packed rectangular photovoltaic cells 5 which are mounted to 64 square modules 23. The array of cells 5 can best be seen in FIG. 2. In the example, each module includes 24 photovoltaic cells 5 arranged in a 6 cell by 4 cell array. The photovoltaic cells 5 are mounted on each module 23 so that the exposed surface of the cell array is a continuous surface. The modules 23 are mounted to the lower wall 99 of the box-like structure of the receiver 7 so that, in this example, the exposed surface of the combined array of photovoltaic cells 5 is in a single plane.

The modules 23 are mounted to the lower wall 99 so that lateral movement between the modules 23 and the reminder of the receiver 7 is possible. The permitted lateral movement assists in accommodating different thermal expansion of components of the receiver 7.

Each module 23 includes a coolant flow path. The coolant flow path is an integrated part of each module 23. The coolant flow path allows coolant to be in thermal contact with the photovoltaic cells 5 and extract heat from the cells 5.

The coolant flow path of the modules 23 forms part of the coolant circuit. The coolant circuit also includes the above described hollow posts 15. In addition, the coolant circuit includes a series of parallel coolant channels 17 that form part of the lower wall 99 of the box-like structure. The ends of the channels 17 are connected to the opposed pair of lower horizontal posts 15 respectively shown in FIG. 4. The lower posts 15 define an upstream header that distributes coolant to the channels 17 and a downstream header that collects coolant from the channels 17. The modules 23 are mounted to the lower surface of the channels 17 and are in fluid communication with the channels so that coolant flows via the channels 17 into and through the coolant flow paths of the modules 23 and back into the channels 17 and thereby cools the photovoltaic cells 5.

The coolant circuit also includes a coolant inlet 61 and a coolant outlet 63. The inlet 61 and the outlet 63 are located in an upper wall of the box-like structure. The inlet 61 is connected to the adjacent upper horizontal post 15 and the outlet 63 is connected to the adjacent upper horizontal post 15 as shown in FIG. 4.

In use, coolant that is supplied from a source (not shown) flows via the inlet 61 into the upper horizontal post 15 connected to the inlet 61 and then down the vertical posts 15 connected to the upper horizontal post 15. The coolant then flows into the upstream lower header 15 and, as is described above, along the channels 17 and the coolant flow paths of the modules 23 and into the downstream lower header 15. The coolant then flows upwardly through the vertical posts 15 that are connected to the downstream lower header 15 and into the upper horizontal post 15. The coolant is then discharged from the receiver 7 via the outlet 63.

Further details of a receiver are found in WO 02/080286 the disclosure of which is incorporated herein. A further module with alternative coolant flow channels defined by sintered rods is described in WO 2005/022652 and can be adapted for use with this embodiment.

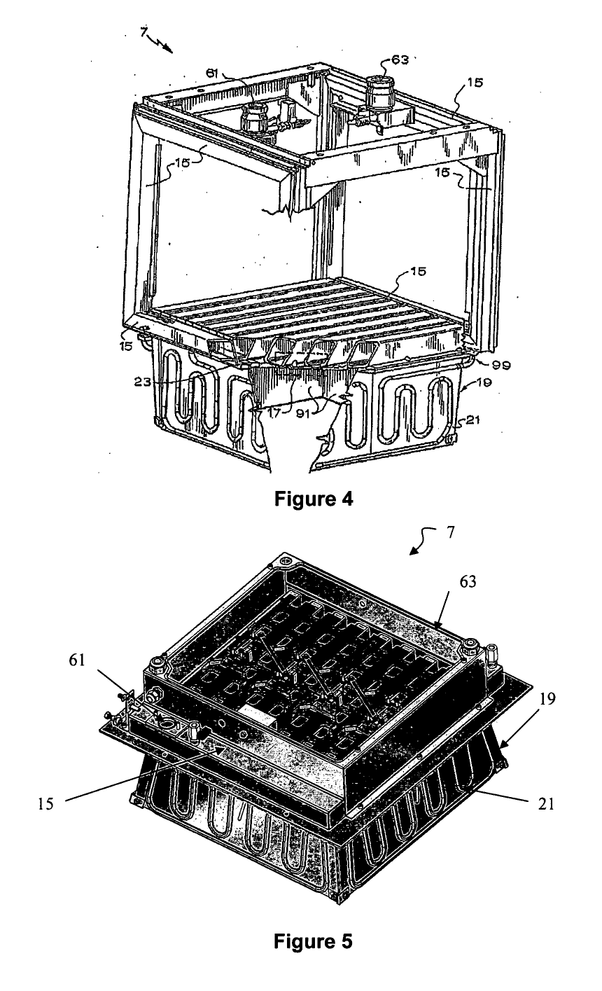

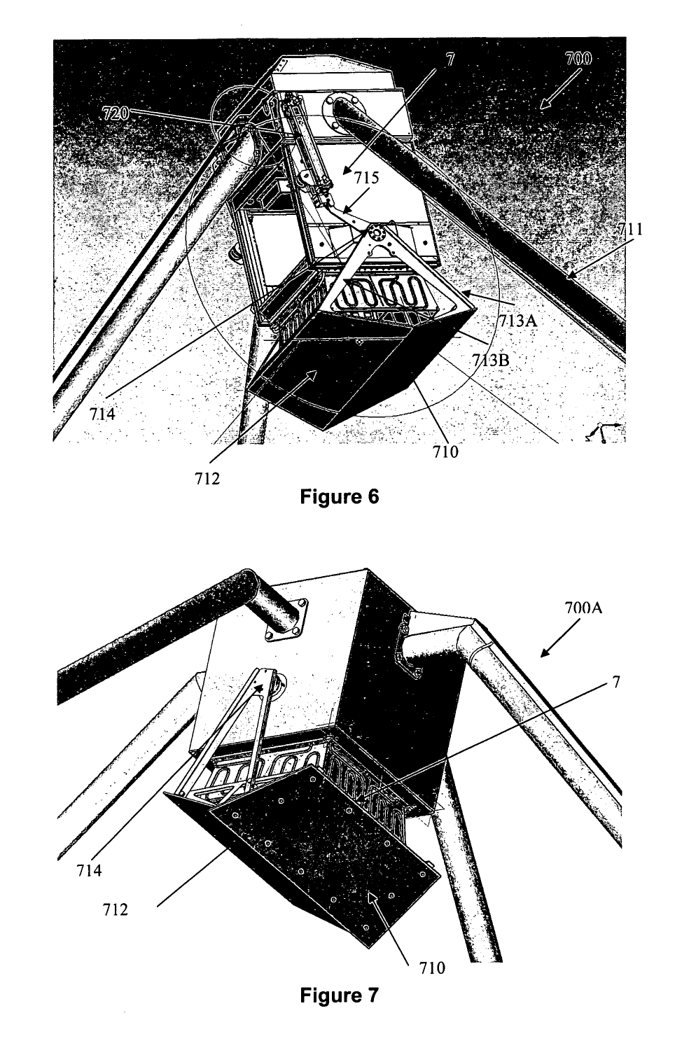

FIGS. 6, 8 and 9 show a protection apparatus 700 of a first embodiment, and having a shield 710 mounted to the receiver 7. The shield 710 is shown in the shielding (FIG. 4) and stowed positions (FIG. 5). The shield is mounted on a support structure comprised of two pairs of arms 713 (the second pair of arms being a mirror of arms 713A,713B) around a pivot point 714.

The front face 712 of shield 710 is sufficiently heat resistant to withstand many exposures to full concentrated sunlight and will protect the receiver as long as it will take for the movement of the sun to direct the solar radiation away from the receiver if the mirrors and receiver are stationary.

In an advantageous embodiment, the front face of the shield exhibits high reflectivity and emissivity to minimise the shield temperature which will in turn increase the lifetime and reduce the cost of the shield. It is also advantageous to have the backside of the shield exhibit a low emissivity which will reduce radiation back to the cells. This will minimise the cell temperature rise during the ‘shielding event’.

In one embodiment, the front face is composed of two sheets of a white refractory ceramic material (RSLE57, Zircar, N.Y.). However, other materials may be used to achieve a shielding effect either by reflecting or absorbing and dissipating the energy by re-radiation. This could be achieved for example by partial reflection and partial radiation.

Conduction or convection using air or a heat transfer fluid could also be used to dissipate the heat energy.

By way of example the back face could be composed of a low emissivity stainless steel sheet separated by an airgap from the(hot)front face. In this manner the combined effect of the lower (emission) temperature of the stainless steel and the low emissivity will keep the cell temperatures lower when in the shield is in the closed position and exposed to the concentrated beam. Other methods or materials may be used to minimise the cell temperature such as applying a low emissivity surface treatment to the back face of the shield.

The supporting structure of shield 710 is designed such that it will accommodate movement due to thermal expansion of the dis-similar materials.

In the embodiment, the two sheets are each 6.6 mm thick and form a structure angled into a v-shape so that in the shielding position, the front face 712 is disposed to be in front of or behind the most concentrated solar radiation at the focal point to thereby encounter lower temperatures—i.e. displaced from the most concentrated solar radiation. The sheets are connected to a steel frame with steel bolts.

Springs are mounted between the receiver body and the shield support structure so as to urge the shield to pivot to the shielding position. An alternative to springs is gravity, where the shield 710 is mounted attached so that gravity provides the passive force toward the shielding position (e.g. for embodiments where the receiver is on a fixed tower rather than a dish).

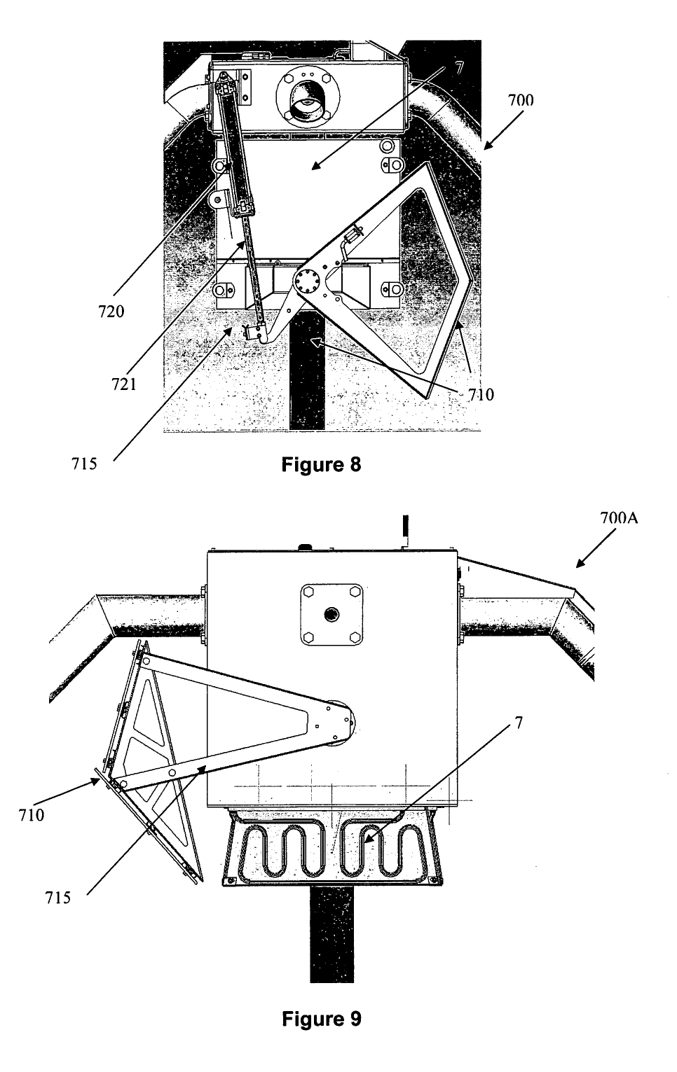

A restraining mechanism is provided by an actuator which in the example protection apparatus 700 of FIGS. 6, 8 and 9 comprises a pair of pneumatic cylinders 720 externally to the receiver mounting box (only one can be seen in FIG. 6) on the opposed mounting faces of the receiver supplied with compressed air from a compressor located on the ground near the mast of the dish (not shown). The compressor only runs periodically, when its reservoir pressure drops below a minimum acceptable level. The arms 721 of the pneumatic cylinders 720 are connected by arm 715 to the support structure such that extending the cylinder arms 721 causes the shield to pivot from the shielding position shown in FIGS. 6 and 7 to the stowed position shown in FIGS. 8 and 8. Accordingly, it will be appreciated that the shield is actively restrained against returning to the shielding position such that if the actuator 720 and 740 is deactivated, the shield 712 is forced to the shielding position by potential energy of the springs (irrespective of the orientation of the receiver 7) such that advantageously there is no need for a powered component which could potentially fail to drive the shield 712 to the shielding position.

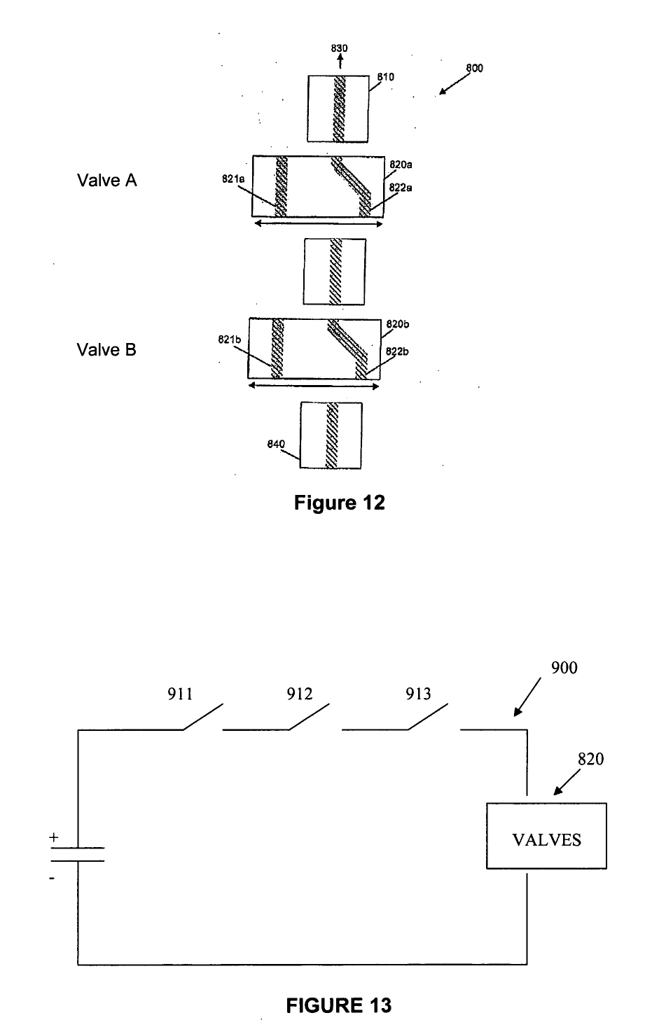

A control mechanism 800 for the pneumatic cylinders 720 of the restraining mechanism is shown in FIGS. 12 and 13. The control mechanism includes a pair of valves 820A, 820B which connect compressed air 840 via connection passages 821 to the pneumatic cylinders when continuously supplied with an activation ‘open shield’ electrical signal on control line 840. The valves 820A, 820B are internally sprung so that lack/loss of electrical signal will cause the valves to go to vent position, where compressed air is vented to atmosphere through venting passages 822 removing the restraint and allowing the shield to be moved to the shielding position by the coil springs. Two valves are used for redundancy, connected in such a way that if any one valve gets stuck in open shield positions, the shield will not be prevented from closing.

The control mechanism includes an electrical circuit 900 shown schematically in FIG. 713. The circuit 900 has a set of switches 911,912,913 responsible for providing the “open shield” electrical signal to the valves. Each switch 911,912,913 represents a criterion required for opening the shield (and/or for the shield to remain open). For the shield to open (sent to the stow position), all criteria must be satisfied (i.e. all switches must be in the “on” position). This logic is achieved by connecting the switches 911,912,913 in series configuration.

In an exemplary embodiment, the switches & criteria are described as follows:

a) Criteria: adequate flow of coolant. Switch: coolant flow switch 911, comprising a mechanical paddle-switch inserted directly in the coolant pipe.

b) Criteria: Adequate compressor pressure. Switch: Compressor pressure interlock 912, controlled by an electrical relay connected to a pressure transducer.

c) Criteria: Temperatures nominal (comprises temperatures measured at several locations on the receiver). Switch: Relay 913 controlled by CPV system control software.

Persons skilled in the art will appreciate that the above criteria are exemplary and other criteria may be used. For example, criteria specific to the actuator being used. Persons skilled in the art will appreciate that many different types of actuators can be employed, both electrical and mechanical, and that these can be connected to the shield in a number of different ways using appropriate coupling techniques. The actuator can also be provided both externally or internally of the receiver mounting box.

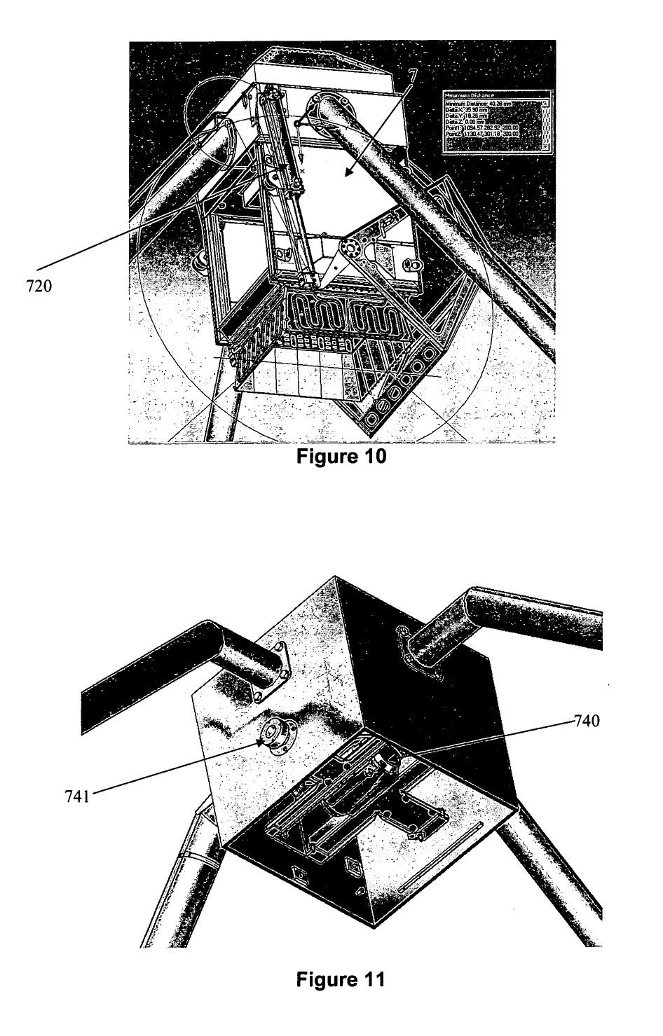

One such technique is provided by a second embodiment of the protection apparatus 700A as shown in FIGS. 7, 9 and 11. The restraining mechanism for the protection apparatus 700A is provided by an actuator in the form of an electrical motor 740 which is mounted internally of receiver mounting box and connected to the shaft 742 around which the shield pivots by gears (not shown). Other linkages could also be used.

A control mechanism for actuator 740 can be provided in an analogous manner to the mechanism shown in FIGS. 12 and 13, for example by replacing the criteria of the compressor processor being adequate with a criteria of the motor power supply being adequate.

Note that other criteria & switches may be added or substituted depending on the necessary protection conditions.

It will be appreciated that the protection apparatus of the embodiment can also be employed with a receiver mounted on a tower and adapted to receive energy from a plurality of heliostats which provide the concentrator.

Further many variations may be made without departing from the scope of the invention. In particular, features of the above embodiments may be employed to form further embodiments.

In the claims which follow and in the preceding description of the invention, except where the context requires otherwise due to express language or necessary implication, the word “comprise” or variations such as “comprises” or “comprising” is used in an inclusive sense, i.e. to specify the presence of the stated features but not to preclude the presence or addition of further features in various embodiments of the invention.

1. Protection apparatus for protecting a photovoltaic solar energy receiver from overheating due to concentrated solar radiation reflected from mirrors towards the receiver, the protection apparatus comprising:
a shield arranged to move between a stowed position out of a path of solar radiation onto the receiver and a shielding position in the path of solar radiation, unless restrained in the stowed position; and
a restraint mechanism for restraining the shield in the stowed position.

2. Protection apparatus as claimed in claim 1, wherein the restraint mechanism restrains the shield when active such that when the restraint mechanism is not active, the shield moves to the shielding position.

3. Protection apparatus as claimed in claim 2, wherein the restraint mechanism comprises at least one actuator, such that the restraint mechanism is active when adequate actuator power supply is supplied.

4. Protection apparatus as claimed in claim 3, wherein each actuator is a pneumatic cylinder such that the restraint mechanism is active when adequate air is supplied to a cylinder chamber of the pneumatic cylinder.

5. Protection apparatus as claimed in claim 4, comprising at least one valve moveable to a venting position to vent compressed from the cylinder chamber to deactivate the restraint mechanism.

6. Protection apparatus as claimed in. claim 5, comprising at least two valves connected such that the movement of either valve to the venting position deactivates the restraint mechanism.

7. Protection apparatus as claimed in claim 3, wherein the actuator is an electric motor coupled to the shield such that the restraint mechanism is active when adequate electric power is supplied to the electric motor.

8. Protection apparatus as claimed in claim 7, wherein the shield is mounted to a shaft around which the shield can rotate and the electric motor is coupled to the shaft.

9. Protection apparatus as claimed in claim 1, wherein the restraint mechanism is moveable from a restraining position to a non-restraining position.

10. Protection apparatus as claimed in claim 1, comprising a shield movement mechanism adapted to move the shield between the stowed position and the shielding position when the shield is not restrained.

11. Protection apparatus as claimed in claim 9, wherein the restraint mechanism restrains the shield by restraining the shield movement mechanism.

12. Protection apparatus as claimed in claim 1, comprising a control mechanism adapted to cause the shield to be moved to the shielding position when at least one protection condition is met.

13. Protection apparatus as claimed in claim 12, wherein the control mechanism deactivates the restraint mechanism when the at least one protection condition is met.

14. Protection apparatus as claimed in claim 13, wherein the control mechanism comprises an electrical circuit and a switch is provided for each protection condition such than when a protection condition is met the associated switch moves to the open position.

15. Protection apparatus as claimed in claim 12, wherein the protection condition comprises at least one of: inadequate coolant flow;
inadequate actuator power supply; and over temperature.

19. Protection apparatus as claimed in claim 12 comprising a control mechanism arranged to control the restraint mechanism such that it moves from the restraining position to the non-restraining position when at least one protection condition is met.

20. Protection apparatus as claimed in claim 1 wherein a front face of the shield is disposed in the shielding position to be displaced relative to the most concentrated solar radiation at a focal point of the concentrated solar radiation to thereby encounter lower temperatures.

21. Protection apparatus as claimed in claim 1, wherein a front face of the shield has high reflectivity.

22. Protection apparatus as claimed in claim 1 wherein a front face of the shield has high emissivity.

23. Protection apparatus as claimed in claim 1, wherein a back face of the shield has low emissivity.

24. A solar power generator comprising:
a photovoltaic solar energy receiver for receiving and converting concentrated solar radiation into electrical power;
at least one concentrator for concentrating the solar radiation on the solar energy receiver; and
a protection apparatus as claimed in claim 1.

25. A method of protecting a photovoltaic solar receiver from overheating due to concentrated solar radiation reflected from mirrors towards the receiver, the protection apparatus comprising:
restraining a shield in a stowed position away from a path of solar radiation onto the receiver; and
causing the shield to move to a shielding position blocking the path of solar radiation when the shield is not restrained in the stowed position.

26. A method of producing electrical power comprising operating the solar power generator of claim 24
